(19) United States
(12) Patent Application Publication
(10) Pub. No.: US 2008/0142862 A1
(43) Pub. Date: Jun. 19, 2008

(54) METHOD OF FABRICATING A TRENCH CAPACITOR HAVING INCREASED CAPACITANCE

(76) Inventors: Sam Liao, Tai-Chung City (TW); Meng-Hung Chen, Tao-Yuan City (TW); Hung-Chang Liao, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/037,090

(22) Filed: Feb. 26, 2008

Related U.S. Application Data
(62) Division of application No. 11/466,105, filed on Aug. 22, 2006.

(30) Foreign Application Priority Data
Aug. 23, 2005 (TW) 094128782

(51) Int. Cl. H01L 29/94

(52) U.S. Cl. 257/303; 257/E27.084

(57) ABSTRACT

The present invention pertains to a method of fabricating a trench capacitor having increased capacitance. To tackle a difficult problem of etching deeper trenches having very high aspect ratio, an epitaxial silicon growth process is employed in the fabrication of next-generation trench DRAM devices. A large-capacitance trench capacitor is first fabricated in the silicon substrate. An epitaxial silicon layer is then grown on the silicon substrate. Active areas, shallow trench isolation regions, and gate conductors are formed on/in the epitaxial silicon layer.

### CROSS REFERENCE TO RELATED APPLICATIONS

This patent application is a divisional application of co-pending U.S. patent application Ser. No. 11/466,105, filed on Aug. 22, 2006 and titled “METHOD OF FABRICATING A TRENCH CAPACITOR HAVING INCREASED CAPACITANCE.” The entire contents of which are incorporated herein by reference.

### BACKGROUND OF THE INVENTION

1. Field of the Invention

The present invention relates generally to the field of semiconductor fabrication and, more particularly, to an improved method of fabricating a trench capacitor structure of dynamic random access memory (DRAM) devices.

2. Description of the Prior Art

Along with the development of miniaturization of various electrical products, DRAM elements have been pushed for size reductions to match the trends toward high integration and high density. DRAM technology faces enormous challenges when reducing the memory cell geometries.

As the line width of fabricating processes is reduced to 0.11 micrometers, the surface area of a trench capacitor is reduced, which directly affects the capacitance. When there is a shortage of capacitance, the information of charges stored in the capacitor is not easily detected, which results in making the capacitance difficult to ascertain. Therefore, increasing the capacitance is an urgent matter of the moment. The capacitance can be expressed by the following formula:

$$C = k \times \frac{A}{d}$$

wherein “C” represents capacitance; “A” represents the area of electrode plate or the capacitor area; “d” represents the thickness of the medium; and “k” represents dielectric constant of the medium. The surface area of the trench capacitor is one of the key factors that affect the capacitance. Therefore, on the condition of fabricating DRAMs with small line widths, manufacturers have to form trench capacitors with greater surface area in order to increase the capacitance.

To make commodity DRAM chips, for instance, manufacturers typically use a process that etches deep trenches in the silicon substrate and coats them with a conductor to create the capacitors. However, etching deep trench into the silicon substrate become more and more difficult as the aspect ratio of the deep trench gets larger. The conventional trench etching and trench fill technology has almost reached its limit. For example, a 7-8 micrometer deep trench is the best that can be done using the conventional trench etching process in 90 nm trench capacitor DRAM process.

In light of the above, there is a constant need in this industry to provide a method capable of enlarging surface area of the deep trench capacitor fabricated at very small design rule of line width, while keeping costs reasonable, though, the extra steps and materials must be kept to a minimum.

### SUMMARY OF THE INVENTION

It is the primary object of the present invention to provide an improved method of fabricating a trench capacitor and trench capacitor DRAM device at very small line width such as 90 nm or below, thereby overcoming the limit of the trench etching techniques and obtaining higher capacitance.

According to the claimed invention, a method of fabricating a trench capacitor is disclosed. The method includes the steps of:

providing a semiconductor substrate having a main surface;

forming a pad layer on the main surface of the semiconductor substrate;

forming a trench in the pad layer and the semiconductor substrate;

forming a lower electrode plate at sidewall and bottom of the trench, wherein the lower electrode plate extends from the bottom to the main surface of the semiconductor substrate;

forming a capacitor dielectric layer on the lower electrode plate;

filling the trench with a first conductive layer;

etching back the first conductive layer to form a recess;

forming a spacer within the recess;

filling the recess with a second conductive layer;

etching back the second conductive layer;

forming a dielectric cap layer on the second conductive layer;

removing the pad layer to expose the main surface of the semiconductor substrate; and

performing epitaxial growth process to grow an epitaxial silicon layer on the exposed main surface of the semiconductor substrate.

From one aspect of this invention, a method of fabricating a trench capacitor dynamic random access memory (DRAM) device is disclosed. The method includes the steps of:

providing a semiconductor substrate having a main surface;

forming a pad layer on the main surface of the semiconductor substrate;

forming a trench in the pad layer and the semiconductor substrate;

forming a lower electrode plate at sidewall and bottom of the trench, wherein the lower electrode plate extends from the bottom to the main surface of the semiconductor substrate;

forming a capacitor dielectric layer on the lower electrode plate;

filling the trench with a first conductive layer;

etching back the first conductive layer to form a recess, wherein the first conductive layer acts as an upper electrode plate, and wherein the first conductive layer, the capacitor dielectric layer and the lower electrode plate constitute a trench capacitor;

forming a spacer within the recess;

filling the recess with a second conductive layer;

etching back the second conductive layer;

forming a dielectric cap layer on the second conductive layer;

removing the pad layer to expose the main surface of the semiconductor substrate; and

performing epitaxial growth process to grow an epitaxial silicon layer on the exposed main surface of the semiconductor substrate;

forming a metal-oxide-semiconductor (MOS) transistor on the epitaxial silicon layer, wherein the MOS transistor has a source/drain region bordering the spacer;

removing a portion of the dielectric cap layer to expose a portion of the second conductive layer; and

forming a conductive local plug which is electrically coupled to the second conductive layer and the source/drain region.

From another aspect of this invention, a trench capacitor dynamic random access memory (DRAM) device is disclosed. The trench capacitor DRAM device includes a semiconductor substrate having a main surface; an epitaxial silicon layer formed on the main surface; a trench in the epitaxial silicon layer and the semiconductor substrate; a capacitor lower electrode formed on sidewall and bottom of the trench and the capacitor lower electrode extending from the bottom of the trench to the main surface of the semiconductor substrate; a capacitor dielectric layer on the capacitor lower electrode; a first conductive layer formed on the capacitor dielectric layer and the capacitor lower electrode, the capacitor dielectric layer and the first conductive layer constitute a trench capacitor; a spacer formed on an upper sidewall of the trench; a second conductive layer formed on the first conductive layer and on the spacer; a metal-oxide-semiconductor (MOS) transistor on the epitaxial silicon layer, wherein the MOS transistor has a source/drain region bordering the spacer; and a conductive plug which is electrically coupled to the second conductive layer and the source/drain region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-14 are schematic, cross-sectional diagrams illustrating the process of fabricating a deep trench capacitor of a DRAM device in accordance with one preferred embodiment of this invention.

### DETAILED DESCRIPTION

The present invention pertains to a method of fabricating a trench capacitor of DRAM devices having increased capacitance. To tackle a difficult problem of etching deeper trenches having a high aspect ratio, an epitaxial silicon growth process is employed in the fabrication of next-generation trench DRAM devices. A large-capacitance trench capacitor is first fabricated in the silicon substrate. An epitaxial silicon layer is then grown on the silicon substrate. Active areas, shallow trench isolation regions, and gate conductors are formed on/in the epitaxial silicon layer.

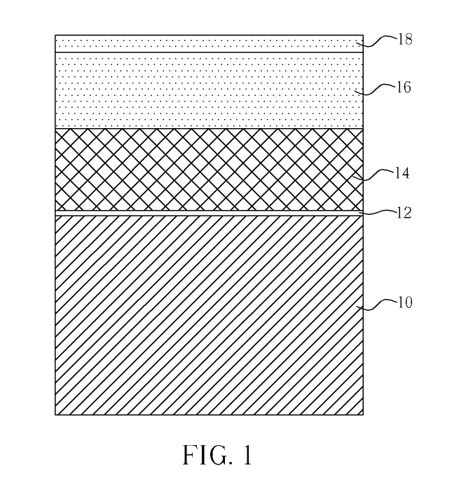

Please refer to FIG. 1 to FIG. 14. FIGS. 1-14 are schematic, cross-sectional diagrams illustrating the process of fabricating a deep trench capacitor of a DRAM device in accordance with one preferred embodiment of this invention. As shown in FIG. 1, a pad oxide layer 12 of about 30 angstroms, a pad nitride layer 14 of about 5000-5500 angstroms, a boron silicate glass (BSG) layer 16 of about 1.5-1.8 micrometers, and a mask layer 18 of about 3000 angstroms are sequentially formed on a semiconductor substrate 10. According to the preferred embodiment, the mask layer 18 is made of polysilicon. It is noteworthy that the thickness of the pad nitride layer 14 (5000-5500 angstroms) is much thicker than that employed in the prior at methods (typically 2000-2500 angstroms).

The pad oxide layer 12 may be formed by thermal oxidation methods or using chemical vapor deposition (CVD) methods. The pad nitride layer 14, the BSG layer 16 and the polysilicon mask layer 18 are formed by CVD methods. The aforesaid CVD methods and thermal oxidation methods are known to those skilled in the art, and the details thereof are omitted for the sake of simplicity.

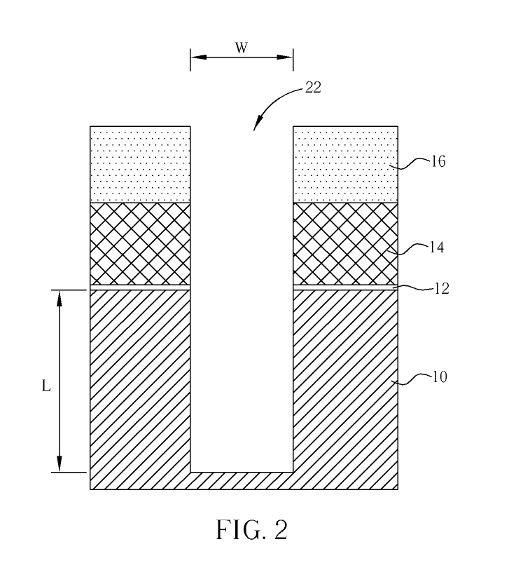

As shown in FIG. 2, a photoresist pattern (not shown) is formed on the mask layer 18. The photoresist pattern has an opening that exposes a deep trench to be etched into the substrate 10. Subsequently, using the photoresist pattern and the mask layer 18 as an etching hard mask, a dry etching process is carried out to etch the mask layer 18, the BSG layer 16, the pad nitride layer 14, the pad oxide layer 12 and the semiconductor substrate 10 through the aforesaid opening in the photoresist pattern, thereby forming a deep trench 22 having a width W and a depth L of about 6-8 micrometers below the main surface of the semiconductor substrate 10.

It is one salient feature of the present invention that the width W of the trench 22 is about 1.3-1.5 F of the critical dimension (CD). The width W of the trench 22 is about the size of the bottle structure of a prior art bottle-shaped capacitor. The capacitance of the trench capacitor according to this invention is equal to, or even exceeds the capacitance of a bottle-shaped capacitor. Besides, the trench 22 has a good etching process window since the trench 22 has a smaller aspect ratio due to the width W of the trench 22 is larger than the prior art that it deepen facilitates the deep trench etching.

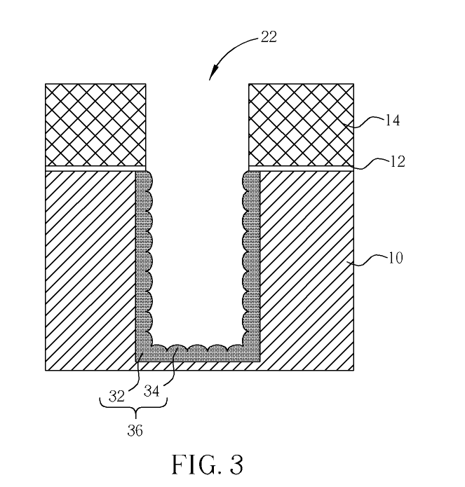

As shown in FIG. 3, the BSG layer 16 is removed. A gas-phase diffusion technology is then employed to form a heavily doped layer 32 on the semiconductor substrate 10 inside the deep trench 22. Preferably, a hemispherical grain (HSG) process is performed to grow a HSG layer 34 on the semiconductor substrate 10 inside the deep trench 22. The heavily doped layer 32 and the HSG layer 34 constitute a lower electrode plate 36 of the deep trench capacitor.

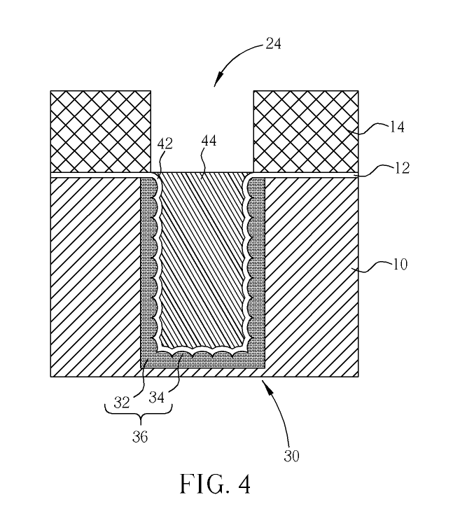

As shown in FIG. 4, a capacitor dielectric layer 42 such as silicon nitride, silicon oxide, silicon nitride/silicon oxide, silicon oxide/silicon nitride/silicon oxide, or any other suitable high dielectric constant materials is formed on the HSG layer 34. Subsequently, a titanium nitride (TiN) CVD process is performed to fill the deep trench 22 with TiN layer 44. The TiN layer 44 is then etched back to form a recess 24. The top surface of the TiN layer 44 is approximately coplanar with the main surface of the semiconductor substrate 10. The TiN layer 44 acts as an upper electrode plate of the deep trench capacitor. The lower electrode plate 36, the capacitor dielectric layer 42 and the upper electrode plate 44 constitute a metal-insulator-silicon (MIS) trench capacitor structure 30.

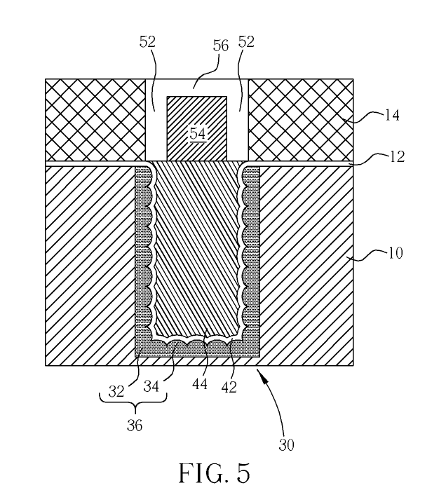

As shown in FIG. 5, a collar oxide layer 52 having a thickness of about 200-300 angstroms is formed on the sidewall of the recess 24. The formation of the collar oxide layer 52 includes the steps of depositing a conformal TEOS oxide layer having a thickness of about 200-400 angstroms that covers the sidewall and the bottom of the recess 24, and anisotropically etching the TEOS oxide layer until the underlying TiN layer 44 is exposed. It is noteworthy that the thickness of the collar oxide layer 52 must be greater than that of the pad oxide layer 12.

After the formation of the collar oxide layer 52, a chemical vapor deposition process is performed to fill the recess with a doped polysilicon layer 54 such as arsenic-doped polysilicon. Subsequently, the doped polysilicon layer 54 is etched back such that the top surface of the doped polysilicon layer 54 is about 500-1000 angstroms lower than the top surface of the pad nitride layer 14. After the etching back of the doped polysilicon layer 54, a silicon oxide cap layer 56 is formed on the doped polysilicon layer 54.

To form the silicon oxide cap layer 56, a chemical vapor deposition process is performed to deposit a silicon oxide layer over the semiconductor substrate 10. The silicon oxide layer covers the doped polysilicon layer 54 and fills the recess 24. Using the pad nitride layer 14 as a polish stop layer, a conventional chemical mechanical polishing (CMP) is carried out to remove the silicon oxide layer outside the recess 24. The remaining silicon oxide layer forms the silicon oxide cap layer 56. It is noteworthy that the thickness of the silicon oxide cap layer 56 must be greater than that of the pad oxide layer 12. According to this preferred embodiment, the silicon oxide cap layer 56 has a thickness of about 600 angstroms.

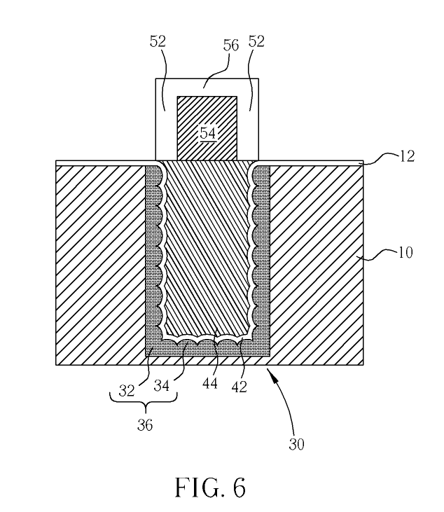

As shown in FIG. 6, the pad nitride layer 14 is removed by using conventional etching methods. For example, the silicon nitride layer 14 may be removed by using wet chemical etching such as heated phosphoric acid solution.

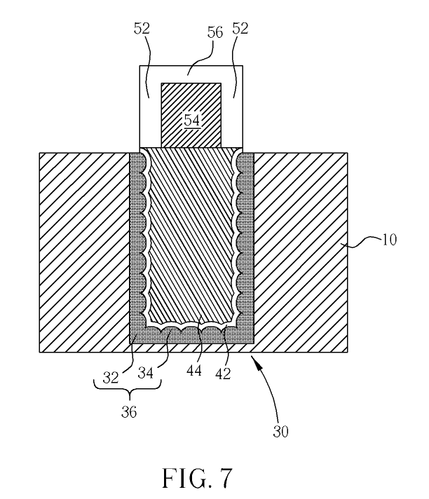

As shown in FIG. 7, the pad oxide layer 12 is removed to expose the main surface of the semiconductor substrate 10. For example, the pad oxide layer 12 may be removed by dipping in diluted hydrofluoric acid (DHF) solution. Simultaneously, a portion of the collar oxide layer 52 and a portion of the silicon oxide cap layer 56 are removed, though the doped polysilicon layer 54 is not exposed.

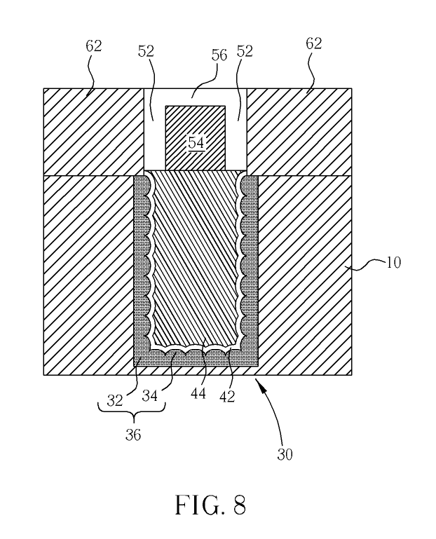

As shown in FIG. 8, an epitaxial silicon layer 62 is grown on the exposed main surface of the semiconductor substrate 10 by using an epitaxial silicon growth process. The epitaxial silicon layer 62 has a thickness of about 5000-6000 angstroms, approximately equal to the thickness of the pad nitride layer 14. Optionally, after the epitaxial silicon growth process, a CMP process may be employed to form a flat surface.

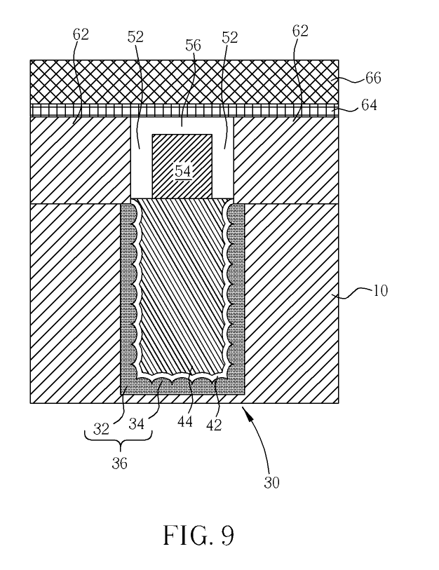

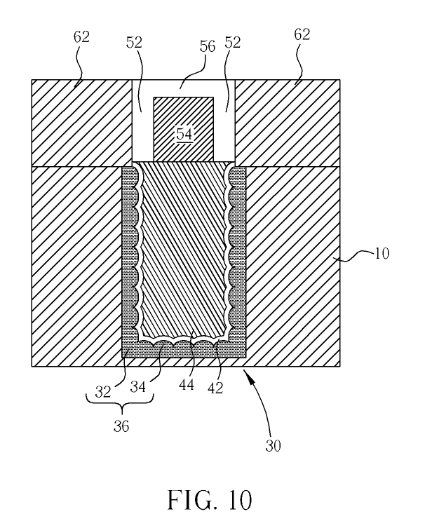

As shown in FIG. 9, a silicon oxide layer 64 and a silicon nitride layer 66 are deposited over the epitaxial silicon layer 62 and the silicon oxide cap layer 56. A conventional shallow trench isolation (STI) process is carried out to form STI structures in the epitaxial silicon layer 62. The aforesaid STI process includes the steps of etching STI trenches into the silicon nitride layer 66, the silicon oxide layer 64 and the epitaxial silicon layer 62 within the non-active areas, filling the STI trenches with trench fill materials, polishing the trench fill material by CMP methods, and annealing. As shown in FIG. 10 after the STI process, the silicon nitride layer 66 and the silicon oxide layer 64 are removed.

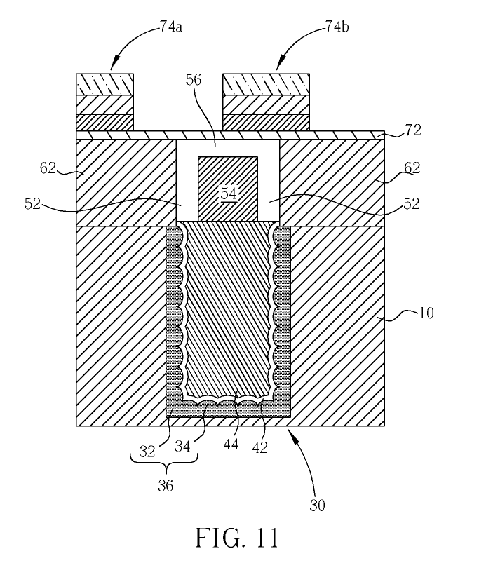

Subsequently, ion wells of desired conductivity types such as N wells or P wells are implanted into the epitaxial silicon layer 62. As shown in FIG. 11, a gate dielectric layer 72 is formed on the active areas defined on and in the epitaxial silicon layer 62. Gate conductor (GC) electrodes 74a and 74b are formed on the gate dielectric layer 72, wherein the GC electrodes 74a is used to control the trench capacitor 30, and the GC electrode 74b overlying the trench capacitor 30 is a passing word line or passing transistor.

The GC electrodes 74a and 74b may comprise a polysilicon layer, a metal silicide layer and a silicon nitride cap layer. According to the preferred embodiment, the GC electrodes 74a and 74b are aligned with the trench capacitor 30 with a lateral shift of ½ F such that the GC electrodes 74b partially overlaps with the underlying trench capacitor 30.

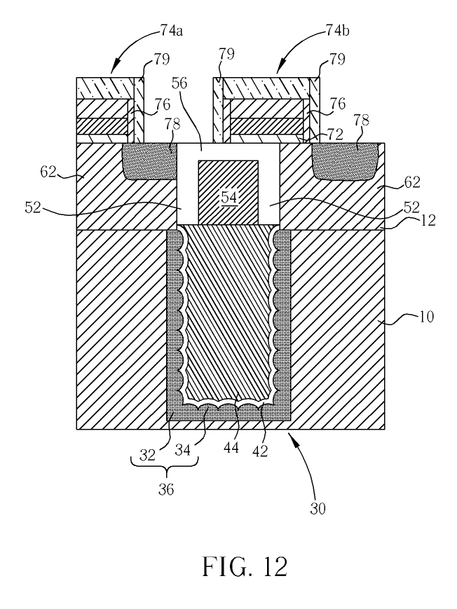

As shown in FIG. 12, the sidewalls of the GC electrodes 74a and 74b are oxidized to form sidewall silicon oxide layers 76. An ion implantation process is carried out to form source/drain regions 78 in the epitaxial silicon layer 62. The source/drain regions 78 are next to the GC electrodes 74a and 74b. Thereafter, a silicon nitride spacer 79 is formed on each sidewall of the GC electrodes 74a and 74b.

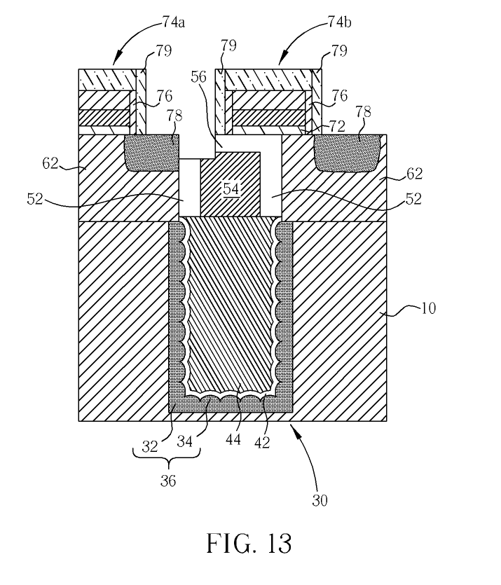

As shown in FIG. 13, an etching process such as DHF wet etching is performed to selectively etching away the silicon oxide cap layer 56 that is not covered by the GC electrode 74b, thereby exposing a portion of the doped polysilicon layer 54.

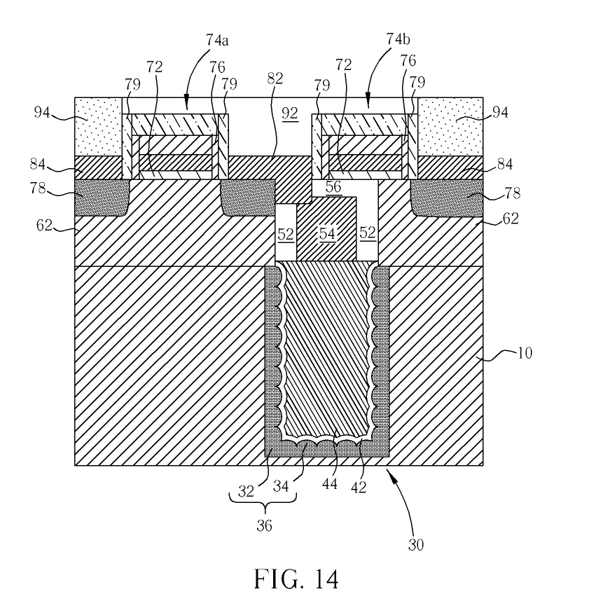

As shown in FIG. 14, a conductive local plug 82 is formed to electrically couple to the doped polysilicon layer 54 and the source/drain region 78 next to the GC electrode 74a. Simultaneously, a conductive local plug 84 is formed on the source/drain region opposite to the conductive local plug 82. According to the preferred embodiment, the conductive local plug 82 is a doped epitaxial silicon layer grown from the exposed surface of the source/drain region 78. In other cases, the conductive local plug 82 may be a doped epitaxial silicon or silicon germanium layer or polysilicon layer. After the formation of the conductive local plug 82, a dielectric layer 92 is deposited over the semiconductor substrate 10. A bit line contact plug 94 is formed on the conductive local plug 84 and is electrically coupled to a bit line (not shown).

It is understood the MIS (metal-insulator-silicon) capacitor structure described in the preferred embodiment is exemplary and should not be limiting. Other capacitor structures such as silicon-insulator-silicon (SIS) or metal-insulator-metal (MIM) may be employed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A trench capacitor of a dynamic random access memory device comprising:
a substrate having a first conductive layer, a dielectric layer and a second conductive layer sequentially formed on a surface of a trench in the substrate;
a silicon layer formed on a top surface of the substrate, and having an opening to expose the second conductive layer, wherein the opening has a spacer formed on a sidewall of the opening;
a third conductive layer formed in the opening and on top of the second conductive layer to be electrically connected to the second conductive layer and surrounded by the spacer; and
a cap layer formed on top of the third conductive layer.

2. The trench capacitor as claimed in claim 1 further comprising a transistor formed on a top surface of the silicon layer to electrically connect to the third conductive layer, and a source/drain region formed in the silicon layer to be adjacent to the spacer.
